(19) United States
(12) Patent Application Publication
(10) Pub. No.: US 2014/0069795 A1
(43) Pub. Date: Mar. 13, 2014

(54) SENSING ARRANGEMENT, SENSOR AND APPARATUS COMPRISING SAME, AND METHOD OF MANUFACTURE THEREOF

(71) Applicants: Hai Zhong ZHANG, Beijing (CN); Qing Yuan TANG, Shanghai (CN); Yan Cheong CHAN, Kowloon (HK)

(72) Inventors: Hai Zhong ZHANG, Beijing (CN); Qing Yuan TANG, Shanghai (CN); Yan Cheong CHAN, Kowloon (HK)

(73) Assignee: CITY UNIVERSITY OF HONG KONG, Kowloon (HK)

(21) Appl. No.: 13/610,097

(22) Filed: Sep. 11, 2012

(51) Int. Cl. H03K 17/98; H01H 11/00

(52) U.S. Cl. 200/600; 29/622

(57) ABSTRACT

The present invention is concerned with a sensing arrangement. The arrangement comprises a plurality of layers laminated together. The layers include sequentially a first layer of electrode, a second layer for insulation, a third layer made principally of polydimethylsiloxane (PDMS) and a fourth layer of electrode. The third layer is provided with an array of micro-structures configured in the form of hemispheres, with convex surface of the hemispheric micro-structures oriented towards the insulation layer.

### FIELD OF THE INVENTION

The present invention is concerned with a sensing arrangement, a sensor or an apparatus comprising such arrangement and a method of manufacture such arrangement.

### BACKGROUND OF THE INVENTION

In recent years, there has been considerable development in different types of sensing technologies for use in different applications. In the arena of electronics industry, for example, a sensing arrangement can be used to provide a touch pad for use in a laptop computer. A sensing arrangement can also be used in a touch screen of a computing tablet.

Tactile sensors are essential in a sensing arrangement. In order for a tactile sensor to function reliably, it must have fairly high sensitivity. Many researches in the past have focused on the use of silicon-based material in making these tactile sensors, and these sensors have been fabricated mainly with the use of conventional micro-electromechanical systems (MEMS) process. These conventional tactile sensors actually have achieved fairly impressive sensitivity. However, depending on the context of the implementation, other characteristics apart from high sensitivity would also be desirable. For example, researches leading to the present invention have shown that sensing arrangements that have a high biocompatibility, flexibility, short-response time, high spatial resolution and are easy to fabricate, etc. would also be desirable.

The present invention seeks to provide an improved sensing arrangement, or at least to provide a useful alternative to the public.

### SUMMARY OF THE INVENTION

According to a first aspect of the invention, there is provided a sensing arrangement comprising a plurality of layers laminated together, the layers including sequentially a first layer of electrode, a second layer for insulation, a third layer made principally of polydimethylsiloxane (PDMS) and a fourth layer of electrode, wherein part of the third layer is provided with an array of micro-structures configured to assume the form of hemispheres, with convex surface of the hemispheric micro-structures oriented towards the insulation layer. The sensing arrangement may take the form of a sheet-like material.

Advantageously, the arrangement may be flexible and/or transparent.

Preferably, the first layer and/or the fourth layer may primarily be made of indium tin oxide (ITO)-PET. The (ITO)-PET layer may be flexible and/or transparent.

The third layer may have one of more the characteristics of being flexible, being transparent or translucent, and/or having a thickness from substantially 0.1-0.3 mm.

In an embodiment, the hemispheric micro-structures may be formed by molding topology to the third layer.

In one embodiment, the hemispheric micro-structures may have a diameter from substantially 20-500 μm or preferably about 200 μm, and the distance between a pair of adjacent hemispheric micro-structures may be from substantially 50-300 μm or preferably about 200 μm. It is however to be noted that the distance between two adjacent micro-structures would depend on the diameter of the micro-structures. When the micro-structures are smaller in diameter, the distance would be smaller.

Suitably, the sensing arrangement may be configured to define sensing sections, each of the sensing sections acting as a sensor unit. In a specific embodiment, each of the sensing sections of the third layer generally may adopt a configuration of a concave square bearing the hemispheric micro-structures. Area of the third layer outside the concave square(s) may be free of said hemispheric micro-structures such that the sensor units are well separated by regions or barriers free of such hemispheric micro-structures, allowing higher sensitivity and spatial resolution of the sensor units.

The sensor unit may have a size of substantially 6 mm×6 mm. The sensing arrangement may comprise an array of the sensor units.

Advantageously, the layers of the sensing arrangement may be sealed together by polydimethylsiloxane (PDMS).

Preferably, the sensing arrangement may be configured to detect a load of 3 mN or greater. Yet preferably, the sensing arrangement may be configured to sense an object with a sensitivity of 2.05 N⁻¹ or greater.

According to a second aspect of the present invention, there is provided a method of fabricating a sensing arrangement with laminated structure, comprising the steps of a) providing a third layer of material made of principally polydimethylsiloxane (PDMS), b) forming hemispheric micro-structures to the third layer by moulding respective topology thereto, c) providing a first layer of electrode, a second layer for insulation and a fourth layer of electrode, d) arranging the layers such that convex surface of the hemispheric micro-structures are oriented towards the second insulation layer, and e) sealing the layers together by polydimethylsiloxane (PDMS).

Preferably, after the sealing in step e), there may be provided with a step of bonding the layers together by heat treatment.

In an embodiment, the method may comprise a step of forming the first layer and/or the fourth layer with indium tin oxide (ITO)-PET.

Suitably, the third layer may be flexible.

The method may comprise a step of configuring the arrangement to define sensing sections representing an array of sensor units, wherein each of the sensing sections of the third layer generally may adopt a configuration of a concave square bearing the hemispheric micro-structures.

According to a third aspect of the present invention, there is provided an electronic device, wherein the device may comprise a sensing arrangement as described above for receiving stimulation. The device may be a computer, a computing tablet, or a limb of a robotic system.

According to a fourth aspect of the present invention, there is provided an electronic paper system, wherein the system may comprise a sensing arrangement as described above.

According to a fifth aspect of the present invention, there is provided an artificial biomedical skin, wherein the skin may comprise a sensing arrangement as described above.

### BRIEF DESCRIPTION OF DRAWINGS

Some embodiments of the present invention will now be explained, with reference to the accompanied drawings, in which:—

FIG. 1a is a schematic view of an embodiment of a sensing arrangement in accordance with the present invention;

FIG. 1b is an image of a transparent layer with patterned electrodes of the sensing arrangement of FIG. 1a;

FIG. 1c is an image of a transparent layer polydimethylsiloxane (PDMS) with micro-structures of the sensing arrangement of FIG. 1a;

FIGS. 2a-b are SEM images showing a cross sectional view and a top view of micro-structured PDMS arrays, respectively, in accordance with an embodiment of the present invention;

FIG. 3a is a graph showing characteristics of pressure-response of the sensing arrangement of FIG. 1a;

FIG. 3b is a graph showing pressure-response characteristics of the sensing arrangement of FIG. 1a when the load is as low as 30 mg; and

FIG. 3c is a diagram showing resolution characteristics of the sensing arrangement of FIG. 1a.

### DETAILED DESCRIPTION OF PREFERRED EMBODIMENTS OF THE INVENTION

There has been considerable research effort on developing assistant robots and artificial biomedical skin, since J. Sullivan demonstrated a first brain-controlled robotic arm. However, in order for biomedical skin to emulate real tactile sensing properties of natural human and to behave as human skin, tactile sensors being able to detect tactile information effectively are indispensable. This is because human beings can dexterously handle a variety of tasks with their hands depending on sophisticated tactile sensor system in the human skin. As such, the tactile sensor units are required to possess, among other traits, high sensitivity.

Some researchers have focused on the use of silicon-based material to fabricate by mainly using some conventional micro-electromechanical systems (MEMS) process. However, such tactile sensors may lack the properties of superior biocompatibility and good flexibility. Studies during the course of the present invention have shown that tactile sensors may employ different flexible polymeric materials such as polymer foam, fabric, polyimide or polydimethylsiloxane (PDMS). Some embodiments of the present invention are concerned with the use of PDMS as a structural material for fabricating a sensing arrangement. Among other advantages, tactile sensors made from PDMS possess the characteristics of good biomedical compatibility with human tissues, relatively high flexibility compared to many other polymers, relatively high chemical stability, and transparency. In other words, it is envisaged that a sensing arrangement made with PDMS in accordance with the present invention can be implanted onto the human body for biomedical use.

In addition to the use of structural material, sensing mechanism of a sensor arrangement is also of great importance for the implementation of high-performance tactile sensors. Although a resistive sensor using conductive rubber thin film as the structural material may be used, such sensors often exhibit rather poor sensitivity when the load pressure is in a low pressure regime. During the course leading to certain aspects of the present invention, it is shown that capacitive tactile sensors, when compared with resistive ones, often have a higher sensitivity and better immunity to temperature. It has also been shown that capacitive sensors based on PDMS polymer often demonstrate excellent sensitivity and short response time. The present invention has demonstrated embodiments of versatile capacitive tactile sensors, possessing an excellent sensitivity with a good resolution when compared with the prior art.

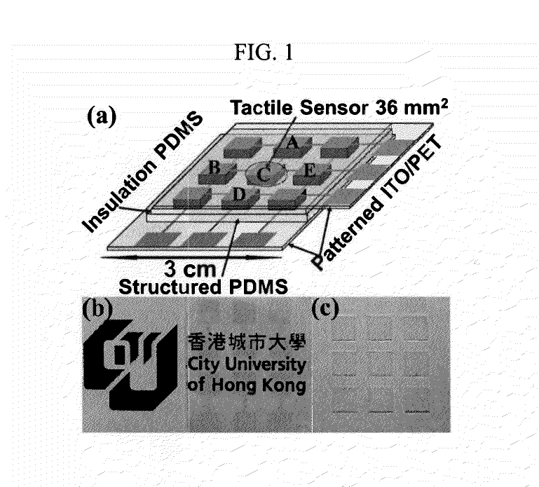

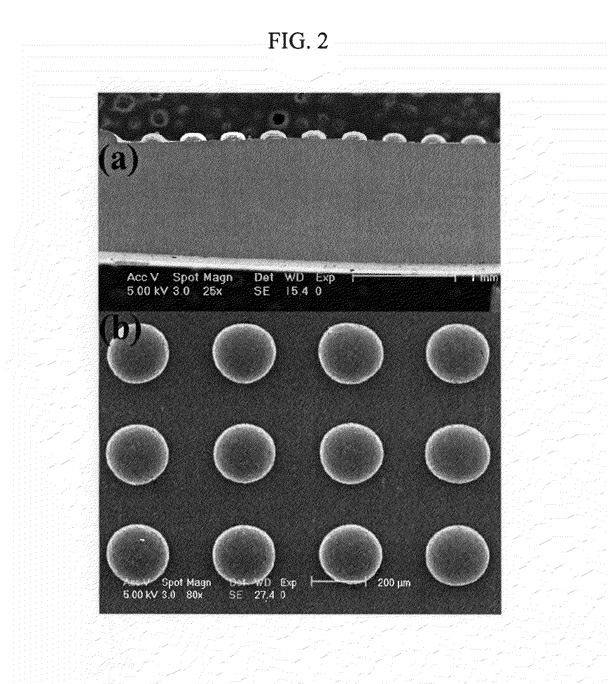

In one embodiment of the present invention, there is provided a sensor arrangement of a sensor. The arrangement comprises a plurality of layers, including a bottom indium tin oxide (ITO)-PET electrode layer, a structured-PDMS layer, an insulation PDMS layer and a top ITO-PET electrode layer arranged sequentially. It is to be noted that each of the layers may be processed separately, and then laminated in sequence. All these layers are then connected together by sealing up with PDMS. Studies have shown that the layers can be bonded together well after hot treatment at 90° C. for about 30 minutes. FIGS. 1a-c illustrate such a sensor arrangement in greater detail.

In FIGS. 1a-c, there are shown an array of sensor units of the sensing arrangement. Specifically, the array has 3×3 sensor units, with each sensor unit being substantially 6×6 mm². FIG. 1a illustrates the schematic structure of tactile sensor arrangement. In this particular embodiment, the sensor arrangement is constructed of fully transparent and flexible materials.

Fabrication of the bottom and the top electrode layers are described herein. ITO-PET film with the ITO thin-film thickness of ˜120 nm is commercially available, and the sheet resistance value of ITO film is 45Ω/□. ITO electrode patterns on the PET film can be created by UV lithographic process with spin-coating SPR6112B photoresist. The spin speed and time are 2000 μm and 60 s, respectively. Subsequently, the photoresist is baked on a hot plate at 95° C. for 10 minutes. The ITO-PET electrode layer is then treated under UV exposure for 4 s, developed with the MIF developer of AZ300 for 45 s, and rinsed in DI water in order. The ITO film is then etched by using diluted concentrated hydrochloric acid (10% HCl) at room temperature for about 35 s. Finally, the photoresist is stripped off with acetone for 10 s. The ITO electrode patterns on PET with good transparency are illustrated, as shown exemplarily in FIG. 1b. The image of transparent ITO/PET layer is shown in FIG. 1b.

In this embodiment of the present invention, the PDMS layer is configured to possess micro-structures which contribute to the performance of the sensing arrangement. The micro-structures are formed by molding topology into the PDMS film, and reside on the third layer from the top. The molding process is conducted by using a mold containing reverse micro-structuring arrays from the desired feature of the PDMS layer. The mold can be designed and obtained by wet-etching copper plate or stainless steel plate, and is commercially available. Also, the mold can be easily fabricated in a laboratory setting. FIG. 1c shows a micro-structured PDMS layer, in which sensing sections are configured to take the form of concave squares with hemispheric micro-structured PDMS arrays of feature size 200 μm and pitch 200 μm. The feature size refers to the diameter of each hemispheric bump while the pitch is the distance between two adjacent hemispheric bumps. The arrays are well separated by other sections without any micro-structured PDMS array.

Fabrication of the micro-structured PDSMS arrangement is now explained. First, the PDMS mixture of base and cross-linker (Sylgard 184 A:B=10:1 in weight) is vacuum-degassed, and poured onto our designed mould. Then the PDMS is cured at a temperature of 90° C. for 60 minutes. After curing, the PDMS film with micro-structured arrays is peeled off from the mould. FIG. 2 illustrates scanning electron microscope (SEM) images of PDMS film with hemispheric micro-structure arrays. Micro-structured arrays owning a mass of voids provide the microstructure surface with enough room to deform elastically in great degree on application of external pressure. Thereby, it becomes relatively effortless for such tactile sensor to store and release the energy reversibly. Furthermore, due to an obvious difference of dielectric constant between voids (∈ₐᵢᵣ˜1.0) and PDMS (∈_{PDMS}˜3.0), capacitive tactile sensor can take full advantage of this property to obtain a high sensing sensitivity. The following provides further explanation on the working of the sensing arrangement.

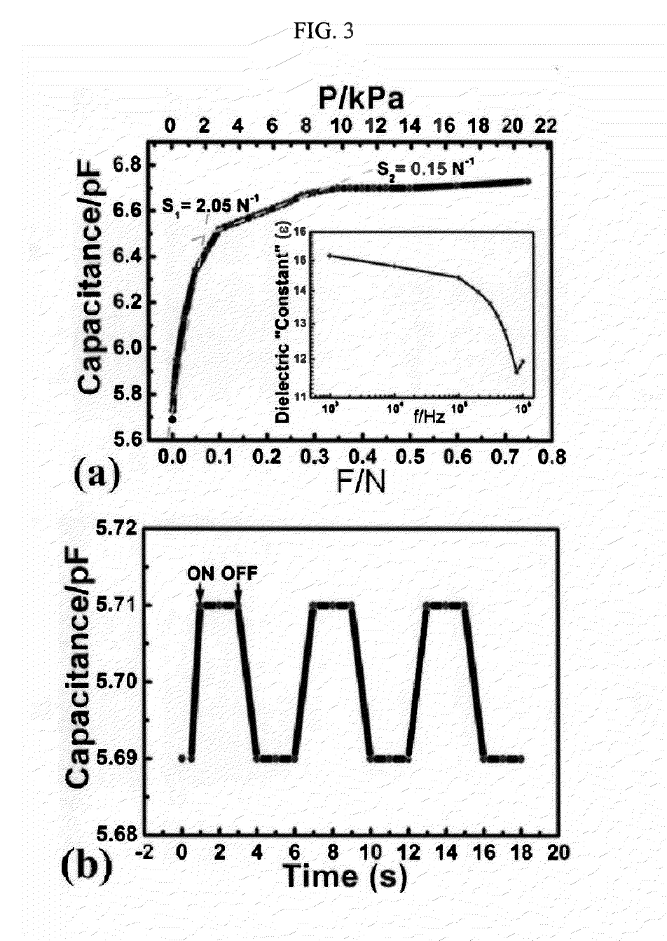

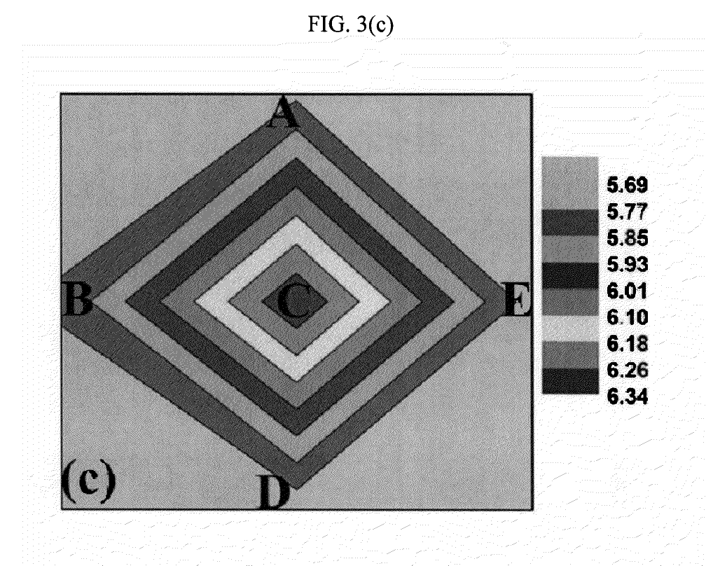

The sensing sensitivity of the tactile sensor was tested by connecting the upper and bottom ITO electrodes onto designed printed circuit board (PCB) with silver pastes. The sensing sensitivity of each sensor unit was characterized with LCR meter, which was wire-connected to the PCB, in the change of capacitance (ΔC) as the exerting external loads. FIG. 3(a) shows the pressure responses (at 1 MHz, 1 V) of tactile unit on the variation of loads. The pressure sensitivity S is defined by using the following expression, and is extracted by taking the slope of the curve in FIG. 3(a).

S=δ(C/C₀)/δF=(1/C₀)*δC/δF, (1)
where F denotes the applied pressure, C and C₀ denote the capacitances with and without applied pressure, respectively.
   The inset depicts the frequency dependency of the complex permittivity of structured PDMS at 1V.

In the test, a small plastic plate of equal size (30 mg) was placed between the sensor surface and the load. It offered an evident benefit that made external pressure uniformly applied to the whole tactile sensor area, and enabled all micro-structured arrays in sensing unit to deform elastically.

It is to be understood that this contributes a good role in the achievement of high-sensitivity tactile sensor. Apart from this, the micro-structured PDMS film also contributes to the excellent sensitive sensor behavior. As explained above, there are a large number of voids in the micro-structured PDMS layer. When external pressure is applied on the sensor, the volume of voids will be occupied by the micro-structured PDMS. As a result, the proportion or area of micro-structured PDMS will increase vigorously, while the volume of the voids will reduce rapidly. To the contrary, the proportion or area of PDMS will increase vigorously. When external pressure is applied on the sensor, the areas of a large number of voids will be occupied by the areas of micro-structured PDMS. Due to a lower dielectric constant of air than PDMS, equivalent dielectric constant increases on application of external pressure, resulting in the booming increase of capacitance. Moreover, the increase in the capacitance is also attributed to the reduction in the distance between two electrode plates. The micro-structures are configured to take the form of micro-hemispheres. Arrays of these hemispheres can deform sooner than if structures of other profiles (e.g. cubes, cylindrical structures, etc.) are used. With these hemispheric micro-structures, only tiny or relatively low pressure exerted on the sensor unit is required. These characteristics contribute to a remarkable sensitivity (S=2.05 N⁻¹) of the tactile sensor even in the low-pressure regime (<2 kPa). Experiments have demonstrated that such tactile sensor with hemispheric micro-structured PDMS arrays can even repeatedly detect load as low as about 3 mN. FIG. 3b demonstrates that the response time is obviously transient switching the sensor from on-state to off-state, or vice versa. It can be illustrated that the response speed of the sensing arrangement is quite rapid. Further, the sensor shows only a little feeble hysteresis when such a low force is loaded or unloaded. There is however a reduction in sensitivity (S=0.15 N⁻¹) of structured sensor in the higher-pressure regime (>2 kPa). This is attributed to the hemispheric arrays as well, the elastic resistance of which increases rapidly with the increased loads. This property of the sensor is desirable in detecting higher pressure and also in improving the range of detectable pressures.

Experiments have been conducted to compare the sensitivity of the sensor based on micro-structured PDMS film with that using unstructured PDMS film when the load is below 5 g, taking the maximum of slope of FIG. 3(a). It is to be noted that the unstructured sensor is hardly of any response to such a load and shows a significantly low sensitivity.

FIG. 3c demonstrates that the novel sensing arrangement also exhibits a great resolution. A, B, C, D and E of FIG. 3c correspond to the sensor units shown in FIG. 1(a), respectively. FIG. 3c shows the response of the test sensor unit C to the application of same load (5 g) on each sensor unit A, B, C, D, and E, separately. The color of light gray corresponds to the initial capacitance (5.69 pF) of sensor unit C before exerting the external pressure. From this figure, it can be seen that the capacitance of the sensing unit C changed from the initial 5.69 pF to 5.77 pF when exerting the external pressure to other sensing units. However, the change in the capacitance of sensing unit C was from the initial 5.69 pF to 6.34 pF when applying the same external pressure to sensing unit C itself. Accordingly, the magnitude of the change in capacitance is large enough to discriminate different sensing areas. The change in capacitance in percentage appears low—this is due to the high based-test capacitance including the high circuit capacitance.

The novel concave square areas of the sensing units with micro-structured arrays also contribute to the good resolution of the sensor. The concave square areas of sensing units with micro-structured PDMS arrays are effectively separated by unstructured PDMS sections, which are acting as the perfect natural wall-barriers.

As depicted in the above embodiments, a sensor arrangement that makes use of PDMS as structural material as illustrated above is advantageous. For example, the arrangement can have an excellent performance with a superior sensitivity of 2.05 N⁻¹ and a high resolution.

It is to be noted while the PDMS layer may be made to be transparent, it may also be made to be translucent for certain applications.

Depending on the particular application, the thickness of the structural PDMS layer may be different. Also, the thickness will depend on the process adopted in the preparation of the PDMS layer. In any event, in order to provide a flexible PDMS layer, the layer may be configured to range from substantially 0.1-0.3 mm.

It should be understood that certain features of the invention, which are, for clarity, described in the content of separate embodiments, may be provided in combination in a single embodiment. Conversely, various features of the invention which are, for brevity, described in the content of a single embodiment, may be provided separately or in any appropriate sub-combinations. It is to be noted that certain features of the embodiments are illustrated by way of non-limiting examples. For example, while different sensor arrangements as illustrated above may be used on laptop computers, computing tablets, they may also be implemented in robots and prosthetic devices for use by humans. In such context, the sensor arrangements may be used for making artificial skin of a robotic arm or a prosthetic arm for use by humans. Also, a skilled person in the art will be aware of the prior art which is not explained in the above for brevity purpose.

1. A sensing arrangement comprising a plurality of layers laminated together, said layers including sequentially a first layer of electrode, a second layer for insulation, a third layer made principally of polydimethylsiloxane (PDMS) and a fourth layer of electrode, wherein part of said third layer is provided with an array of micro-structures configured to take the form of hemispheres, with convex surface of said hemispheric micro-structures oriented towards said insulation layer.

2. A sensing arrangement as claimed in claim 1, wherein said arrangement is flexible and/or transparent.

3. A sensing arrangement as claimed in claim 1, wherein said first layer and/or said fourth layer are/is primarily made of indium tin oxide (ITO)-PET.

4. A sensing arrangement as claimed in claim 1, wherein said third layer is flexible.

5. A sensing arrangement as claimed in claim 1, wherein said third layer is transparent.

6. A sensing arrangement as claimed in claim 1, wherein said third layer is translucent.

7. A sensing arrangement as claimed in claim 1, wherein said third layer has a thickness from substantially 0.1-0.3 mm.

8. A sensing arrangement as claimed in claim 1, wherein said hemispheric micro-structures are formed by molding topology to said third layer.

9. A sensing arrangement as claimed in claim 1, wherein said hemispheric micro-structures have a diameter from substantially 20-500 μm or preferably about 200 μm, and the distance between a pair of adjacent hemispheric micro-structures is from substantially 50-300 μm or preferably about 200 μm.

10. A sensing arrangement as claimed in claim 1, configured to define sensing sections, each of said sensing sections acting as a sensor unit.

11. A sensing arrangement as claimed in claim 10, wherein each of said sensing sections of said third layer generally adopts a configuration of a concave square bearing said hemispheric micro-structures.

12. A sensing arrangement as claimed in claim 11, wherein area of said third layer outside the concave square(s) is free of said hemispheric micro-structures such that said sensor units are well separated, allowing higher sensitivity and spatial resolution of said sensor units.

13. A sensing arrangement as claimed in claim 9, wherein said sensor unit has a size of substantially 6 mm×6 mm.

14. A sensing arrangement as claimed in claim 9, comprising an array of said sensor units.

15. A sensing arrangement as claimed in claim 1, wherein said layers are sealed together by polydimethylsiloxane (PDMS).

16. A sensing arrangement as claimed in claim 1, configured to detect a load of 3 mN or greater.

17. A sensing arrangement as claimed in claim 1, configured to sense an object with a sensitivity of 2.05 N⁻¹ or greater.

18. A method of fabricating a sensing arrangement with laminated structure, comprising steps of:
a) providing a third layer of material made of principally polydimethylsiloxane (PDMS);
b) forming hemispheric micro-structures to the third layer by moulding respective topology thereto;
c) providing a first layer of electrode, a second layer for insulation and a fourth layer of electrode;
d) arranging the layers such that convex surface of the hemispheric micro-structures are oriented towards the second insulation layer; and
e) sealing the layers together by polydimethylsiloxane (PDMS);

19. A method as claimed in claim 18, comprising a step, after said sealing in step e), of bonding the layers together by heat treatment.

20. A method as claimed in claim 18, comprising a step of forming the first layer and/or the fourth layer with indium tin oxide (ITO)-PET.

21. A method as claimed in claim 18, wherein the third layer is flexible and/or transparent.

22. A method as claimed in claim 18, comprising a step of configuring the arrangement to define sensing sections representing an array of sensor units, wherein the third layer of each or least some of the sensing sections generally adopt a configuration of concave square bearing the hemispheric micro-structures.
